(19) United States
(12) Patent Application Publication
(10) Pub. No.: US 2025/0204159 A1
(43) Pub. Date: Jun. 19, 2025

(54) DISPLAY APPARATUS HAVING A CHARGE GENERATION LAYER

(71) Applicant: LG Display Co., Ltd., Seoul (KR)

(72) Inventors: Hee Tae LIM, Paju-si (KR); Byung Gun AHN, Paju-si (KR); Bo Min SEO, Paju-si (KR); Sung Min JO, Paju-si (KR)

(21) Appl. No.: 18/760,891

(22) Filed: Jul. 1, 2024

(30) Foreign Application Priority Data
Dec. 13, 2023 (KR) 10-2023-0180747

(51) Int. Cl. H10K 59/122; H10K 59/00; H10K 59/80

(52) U.S. Cl. CPC H10K 59/122; H10K 59/771; H10K 59/8792

(57) ABSTRACT

A display apparatus including a light-emitting device is provided. The light-emitting device may be disposed on an emission area. A light-emitting unit of the light-emitting device may include a charge generation layer between a first emission stack and a second emission stack. A non-emission area may be disposed outside the emission area. A bank insulating layer may be disposed on the non-emission area. The charge generation layer may extend onto the bank insulating layer. A first region of the charge generation layer overlapping with the bank insulating layer may have a resistance greater than a second region of the charge generation layer overlapping with the emission area. Thus, in the display apparatus, light leakage due to leakage current may be prevented.

### CROSS-REFERENCE TO RELATED APPLICATIONS

This application claims the benefit of Korean Patent Application No. 10-2023-0180747, filed on Dec. 13, 2023, which is hereby incorporated by reference as if fully set forth herein.

### BACKGROUND

### Technical Field

The present disclosure relates to a display apparatus in which a light-emitting unit of a light-emitting device includes a charge generation layer between a first emission stack and a second emission stack.

### Description of the Related Art

Generally, a display apparatus provides an image to a user. For example, the display apparatus may include a plurality of light-emitting devices. The light-emitting device may emit light displaying a specific color. For example, the light-emitting device may have a light-emitting unit disposed between a first electrode and a second electrode.

The light-emitting unit may include at least two emission material layers. For example, the light-emitting unit may have a stacked structure of a first emission stack and a second emission stack. Each of the first emission stack and the second emission stack may include at least one emission material layer. Each of the first emission stack and the second emission stack may emit light. For example, a charge generation layer may be disposed between the first emission stack and the second emission stack. The charge generation layer may supply holes or electrons to the first emission stack and the second emission stack.

### BRIEF SUMMARY

The light generated by each emission stack may display a same color as the light generated by adjacent emission stack. For example, the charge generation layer of each light-emitting device may be electrically connected to the charge generation layer of adjacent light-emitting device. Thus, in the display apparatus, current applied to each light-emitting device may be supplied to adjacent light-emitting device through the charge generation layer. The inventors of the present disclosure have identified that, in the display apparatus, light may be generated and emitted in an unintended area due to the current leaked through the charge generation layer.

Accordingly, the present disclosure is directed to a display apparatus that substantially obviates one or more technical problems due to limitations and disadvantages of the related art including the technical problem identified above.

Various embodiments of the present disclosure provide a display apparatus capable of preventing the generation and the emission of the light in the unintended area.

Various embodiments of the present disclosure provide a display apparatus in which the driving current applied to the light-emitting device of each emission area may not flow to the outside of the corresponding emission area.

Additional advantages, technical benefits, and features of the disclosure will be set forth in part in the description which follows and in part will become apparent to those having ordinary skill in the art upon examination of the following or may be learned from practice of the disclosure. The benefits and other advantages of the disclosure may be realized and attained by the structure particularly pointed out in the written description and claims hereof as well as the appended drawings.

To achieve these benefits and other advantages and in accordance with the purpose of the present disclosure, as embodied and broadly described herein, there is provided a display apparatus comprising a device substrate. A first light-emitting device is disposed on a first emission area of the device substrate. The first light-emitting device includes a first electrode, a first light-emitting unit and a second electrode, which are sequentially stacked. A bank insulating layer is disposed on a non-emission area of the device substrate. The first emission area is defined by the bank insulating layer. An encapsulation structure is disposed on the first light-emitting device and the bank insulation structure. The light-emitting unit includes a charge generation layer between a first emission stack and a second emission stack. The charge generation layer includes a first region between the bank insulating layer and the encapsulation structure, and a second region overlapping with the first emission area. The first region of the charge generation layer has a greater resistance than a second region of the charge generation layer.

The first region of the charge generation layer may have a smaller thickness than the second region of the charge generation layer.

The charge generation layer may have a stacked structure of n-type charge generating layer and a p-type charge generating layer. At least one of the n-type charge generating layer and the p-type charge generating layer may include a surface treatment portion disposed in the first region.

The surface treatment portion has hydrophobicity.

The p-type charge generating layer may be disposed on the n-type charge generating layer. The surface treatment portion may be disposed at an upper portion of the n-type charge generating layer being in contact with the p-type charge generating layer. A portion of the p-type charge generating layer being in contact with the surface treatment portion may have a smaller thickness than a portion of the p-type charge generating layer disposed outside the surface treatment portion.

The bank insulating layer may include a light-absorbing material.

Each of the emission stacks may include at least one emission material layer. The emission material layer of each emission stack is disposed outside the first region.

A second light-emitting device is disposed on a second emission area of the device substrate. The non-emission area may be disposed between the first emission area and the second emission area. The second light-emitting layer may include emission stacks and a charge generation layer between the emission stacks. The charge generation layer of the second light-emitting device may be in contact with the charge generation layer of the first light-emitting device between the bank insulating layer and the encapsulation structure.

In another embodiment, there is provided a display apparatus comprising a device substrate. A first electrode is disposed on an emission area of a device substrate. A bank insulating layer is disposed on a non-emission area of the device substrate. A light-emitting unit is disposed on the first electrode and the bank insulating layer. A second electrode is disposed on the light-emitting unit. The light-emitting unit has a stacked structure of a first emission stack, a charge generation layer and a second emission stack. A resistance between the first emission stack and the second emission stack on the bank insulating layer is larger than a resistance between the first emission stack and the second emission stack on the emission area.

Each of the first emission stack and the second emission stack may include at least one emission material layer. Light generated by the second emission stack may display a different color from light generated by the first emission stack.

The bank insulating layer may include a first bank region and a second bank region. The second bank region may have a greater thickness than the first bank region. The second bank region may be disposed between the first bank region and the emission area. A resistance between the first emission stack and the second electrode on the second bank region may be smaller than a resistance between the first emission stack and the second electrode on the first bank region.

The resistance between the first emission stack and the second electrode on the second bank region may be a same as a resistance between the first emission stack and the second electrode on the emission area.

A thickness difference between the first bank region and the second bank region may be greater than a thickness of the charge generation layer.

The second bank region may include a first insulating pattern and a second insulating pattern. The first insulating pattern may have a same thickness as the first bank region. The second insulating pattern may be disposed on the first insulating pattern. A side surface of the second insulating pattern toward the first bank region may have a reverse taper shape. A portion of the charge generation layer on the first bank region may be separated from a portion of the charge generation layer on the second bank region by the side surface of the second insulating pattern.

The second emission stack may include a functional layer being in contact with the charge generation layer. The functional layer on the bank insulating layer may include a region having a smaller thickness than the functional layer on the emission area.

### BRIEF DESCRIPTION OF THE SEVERAL VIEWS OF THE DRAWINGS

The accompanying drawings, which are included to provide a further understanding of the present disclosure and are incorporated in and constitute a part of this application, illustrate embodiment(s) of the present disclosure and together with the description serve to explain the principle of the present disclosure. In the drawings:

FIG. 1 is a view schematically showing a display apparatus according to an embodiment of the present disclosure;

FIG. 2 is a view showing a circuit of a pixel area in the display apparatus according to the embodiment of the present disclosure;

FIG. 3 is an enlarged view of K1 region in FIG. 1;

FIG. 4 is a view taken along I-I′ of FIG. 3;

FIG. 5 is an enlarged view of K2 region and K3 region in FIG. 4; and

FIGS. 6 to 15 are views showing the display apparatus according to another embodiment of the present disclosure.

### DETAILED DESCRIPTION

Hereinafter, details related to the above objects, technical configurations, and operational effects of the embodiments of the present disclosure will be clearly understood by the following detailed description with reference to the drawings, which illustrate some embodiments of the present disclosure. Here, the embodiments of the present disclosure are provided in order to allow the technical sprit of the present disclosure to be satisfactorily transferred to those skilled in the art, and thus the present disclosure may be embodied in other forms and is not limited to the embodiments described below.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

In addition, the same or similar elements may be designated by the same reference numerals throughout the specification and in the drawings.

It will be understood that, when a first element is referred to as being “on” a second element, although the first element may be disposed on the second element so as to come into contact with the second element, a third element may be interposed between the first element and the second element.

Here, terms such as, for example, “first” and “second” may be used to distinguish any one element with another element. However, the first element and the second element may be arbitrary named according to the convenience of those skilled in the art without departing the technical sprit of the present disclosure.

The terms used in the specification of the present disclosure are merely used in order to describe particular embodiments, and are not intended to limit the scope of the present disclosure. For example, an element described in the singular form is intended to include a plurality of elements unless the context clearly indicates otherwise. In addition, in the specification of the present disclosure, it will be further understood that the terms “comprises” and “includes” specify the presence of stated features, integers, steps, operations, elements, components, and/or combinations thereof, but do not preclude the presence or addition of one or more other features, integers, steps, operations, elements, components, and/or combinations.

And, unless ‘directly’ is used, the terms “connected” and “coupled” may include that two components are “connected” or “coupled” through one or more other components located between the two components.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

### Embodiment

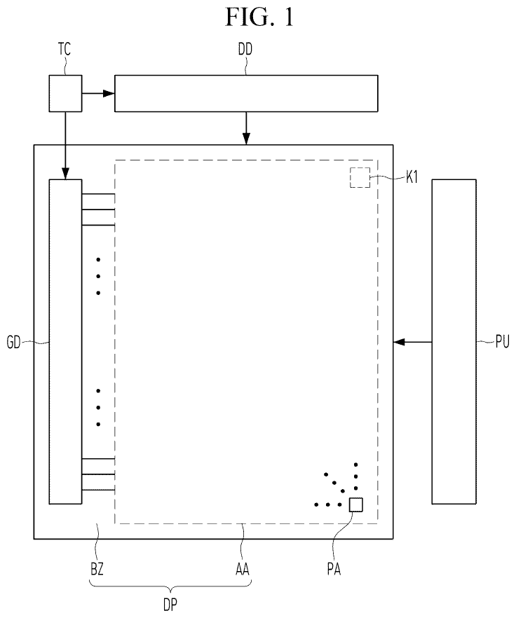

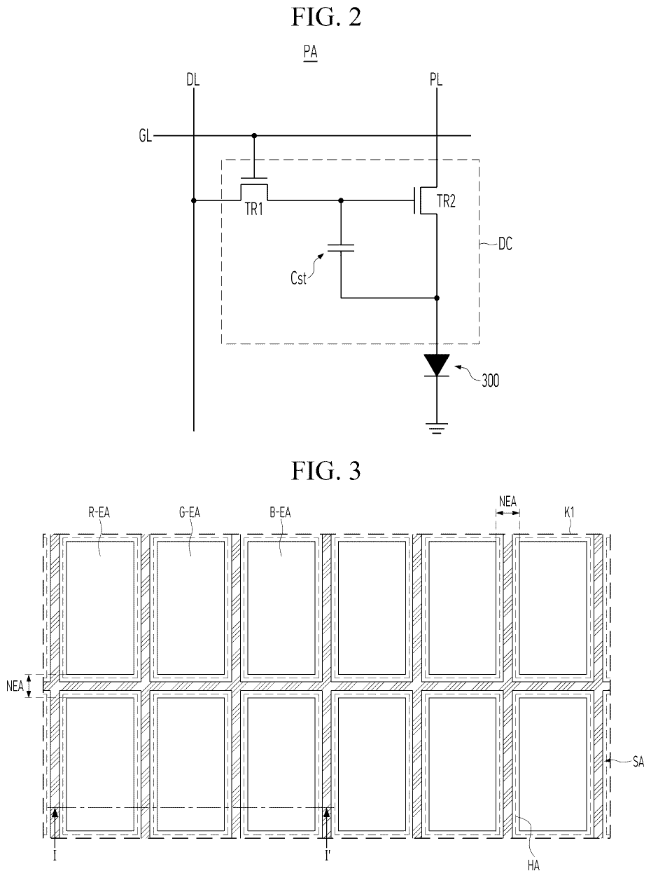

FIG. 1 is a view schematically showing a display apparatus according to an embodiment of the present disclosure. FIG. 2 is a view showing a circuit of a pixel area in the display apparatus according to the embodiment of the present disclosure.

Referring to FIGS. 1 and 2, the display apparatus according to the embodiment of the present disclosure may include a display panel DP. The display panel DP may generate an image provided to a user. For example, the display panel DP may include a plurality of pixel area PA. Various signals may be provided in each pixel area PA through signal wirings GL, DL and PL. For example, the signal wirings GL, DL and PL may include gate lines GL sequentially applying a gate signal, data lines DL applying a data signal, and power lines PL supplying a positive power voltage.

The gate lines GL may be electrically connected to a gate driver GD. The data lines DL may be electrically connected to a data driver DD. The power lines PL may be electrically connected to a power unit PU. The gate driver GD and the data driver DD may be controlled by a timing controller TC. For example, the gate driver GD may receive clock signals, reset signals and a start signal from the timing controller TC, and the data driver DD may receive digital video data and a source timing signal from the timing controller TC.

The display panel DP may include the active area AA in which the pixel areas PA are disposed, and a bezel area BZ disposed outside the active area AA. The bezel area BZ may be disposed outside the pixel areas PA. For example, the active area AA may be surrounded by the bezel area BZ. The gate driver GD, the data driver DD, the power unit PU and the timing controller TC may be disposed outside the active area AA. For example, each of the signal wirings GL, DL and PL may include a region on the bezel area BZ.

At least one of the gate driver GD, the data driver DD, the power unit PU and the timing controller TC may be disposed on the bezel area BZ. For example, the display apparatus according to the embodiment of the present disclosure may be a GIP (Gate In Panel) type display apparatus in which the gate driver GD is formed on the bezel area BZ of the display panel DP.

Each of the pixel areas PA may realize a specific color. For example, a light-emitting device 300 electrically connected to a driving circuit DC may be disposed in each pixel area PA. The driving circuit DC of each pixel area PA may electrically connected to the signal wirings GL, DL and PL. For example, the driving circuit DC of each pixel area PA may be connected to one of the gate lines GL, one of the data lines DL and one of the power voltage supply lines PL. The driving circuit DC of each pixel area PA may supply a driving current corresponding to the data signal to the light-emitting device 300 of the corresponding pixel area PA according to the gate signal for one frame. For example, the driving circuit DC of each pixel area PA may include a first thin film transistor TR1, a second thin film transistor TR2 and a storage capacitor Cst.

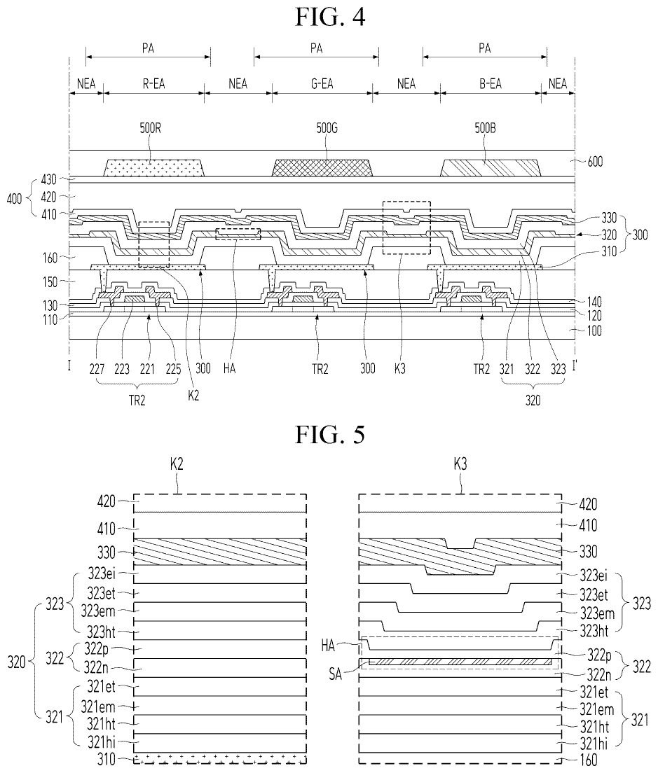

FIG. 3 is an enlarged view of K1 region in FIG. 1. FIG. 4 is a view taken along I-I′ of FIG. 3. FIG. 5 is an enlarged view of K2 region and K3 region in FIG. 4.

Referring to FIGS. 2 to 5, the first thin film transistor TR1 of each pixel area PA may transmit the data signal to the second thin film transistor TR2 of the corresponding pixel area PA according to the gate signal. For example, the first thin film transistor TR1 of each pixel area PA may be a switching thin film transistor. The first thin film transistor TR1 of each pixel area PA may include a first semiconductor pattern, a first gate electrode, a first drain electrode and a first source electrode. For example, the first gate electrode of each pixel area PA may be electrically connected to the corresponding gate line GL, and the first drain electrode of each pixel area PA may be electrically connected to the corresponding date line DL.

The first semiconductor pattern may include a semiconductor material. For example, the first semiconductor pattern may include amorphous silicon (a-Si), polycrystalline silicon (poly-Si) or an oxide semiconductor, such as IGZO. The first semiconductor pattern may include a first drain region, a first channel region and a first source region. The first channel region may be disposed between the first drain region and the first source region. The first drain region and the first source region may have a smaller resistance than the first channel region. For example, the first drain region and the first source region may include a conductive region of an oxide semiconductor. The first channel region may be a region of an oxide semiconductor, which is not conductorized.

The first gate electrode may be disposed on a portion of the first semiconductor pattern. For example, the first gate electrode may overlap the first channel region of the first semiconductor pattern. The first gate electrode may include a conductive material. For example, the first gate electrode may include a metal, such as aluminum (Al), chrome (Cr), copper (Cu), molybdenum (Mo), titanium (Ti) and tungsten (W). The first gate electrode may be spaced apart from the first semiconductor pattern. The first gate electrode may be insulated from the first semiconductor pattern. For example, the first drain region of the first semiconductor pattern may be electrically connected to the first source region of the first semiconductor pattern according to a voltage applied to the first gate electrode.

The first drain electrode may include a conductive material. For example, the first drain electrode may include a metal, such as aluminum (Al), chrome (Cr), copper (Cu), molybdenum (Mo), titanium (Ti) and tungsten (W). The first drain electrode may include a material different from the first gate electrode. For example, the first drain electrode may be disposed on a layer different from the first gate electrode. The first drain electrode may be electrically connected to the first drain region of the first semiconductor pattern. The first drain electrode may be insulated from the first gate electrode.

The first source electrode may include a conductive material. For example, the first source electrode may include a metal, such as aluminum (Al), chrome (Cr), copper (Cu), molybdenum (Mo), titanium (Ti) and tungsten (W). The first source electrode may include a material different from the first gate electrode. The first source electrode may be disposed on a layer different from the first gate electrode. For example, the first source electrode may be disposed on a same layer as the first drain electrode. The first source electrode may include a same material as the first drain electrode. The first source electrode may be formed by a same process as the first drain electrode. For example, the first source electrode may be formed simultaneously with the first drain electrode. The first source electrode may be electrically connected to the first source region of the first semiconductor pattern. The first source electrode may be insulated from the first gate electrode. The first source electrode may be spaced apart from the first drain electrode.

The second thin film transistor TR2 of each pixel area PA may generate the driving current corresponding to the data signal. For example, the second thin film transistor TR2 of each pixel area PA may be a driving thin film transistor. The second thin film transistor TR2 of each pixel area PA may include a second semiconductor pattern 221, a second gate electrode 223, a second drain electrode 225 and a second source electrode 227. For example, the second gate electrode 223 of each pixel area PA may be electrically connected to the first source electrode of the corresponding pixel area PA, and the second drain electrode 225 of each pixel area PA may be electrically connected to the corresponding power line PL.

The second semiconductor pattern 221 may include a semiconductor material. For example, the second semiconductor pattern 221 may include amorphous silicon (a-Si), polycrystalline silicon (poly-Si) or an oxide semiconductor, such as IGZO. The second semiconductor pattern 221 may include a same material as the first semiconductor pattern. The second semiconductor pattern 221 may be disposed on a same layer as the first semiconductor pattern. The second semiconductor pattern 221 may be formed by a same process as the first semiconductor pattern. For example, the second semiconductor pattern 221 may be formed simultaneously with the first semiconductor pattern.

The second semiconductor pattern 221 may include a second drain region, a second channel region and a second source region. The second channel region may be disposed between the second drain region and the second source region. The second drain region and the second source region may have a resistance smaller than the second channel region. For example, the second drain region and the second source region may include a conductive region of an oxide semiconductor. The second channel region may be a region of an oxide semiconductor, which is not conductorized.

The second gate electrode 223 may be disposed on a portion of the second semiconductor pattern 221. For example, the second gate electrode 223 may overlap the second channel region of the second semiconductor pattern 221. The second gate electrode 223 may include a conductive material. For example, the second gate electrode 223 may include a metal, such as aluminum (Al), chrome (Cr), copper (Cu), molybdenum (Mo), titanium (Ti) and tungsten (W). The second gate electrode 223 may be spaced apart from the second semiconductor pattern 221. The second gate electrode 223 may be insulated from the second semiconductor pattern 221. For example, the second channel region of the second semiconductor pattern 221 may have an electrical conductivity corresponding to a voltage applied to the second gate electrode 223.

The second drain electrode 225 may include a conductive material. For example, the second drain electrode 225 may include a metal, such as aluminum (Al), chrome (Cr), copper (Cu), molybdenum (Mo), titanium (Ti) and tungsten (W). The second drain electrode 225 may include a material different from the second gate electrode 223. For example, the second drain electrode 225 may be disposed on a layer different from the second gate electrode 223. The second drain electrode 225 may be electrically connected to the second drain region of the second semiconductor pattern 221. The second drain electrode 225 may be insulated from the second gate electrode 223.

The second drain electrode 225 may include a same material as the first drain electrode. The second drain electrode 225 may be disposed on a same layer as the first drain electrode. The second drain electrode 225 may be formed by a same process as the first drain electrode. For example, the second drain electrode 225 may be formed simultaneously with the first drain electrode.

The second source electrode 227 may include a conductive material. For example, the second source electrode 227 may include a metal, such as aluminum (Al), chrome (Cr), copper (Cu), molybdenum (Mo), titanium (Ti) and tungsten (W). The second source electrode 227 may include a material different from the second gate electrode 223. The second source electrode 227 may be disposed on a layer different from the second gate electrode 223. For example, the second source electrode 227 may be disposed on a same layer as the second drain electrode 225. The second source electrode 227 may include a same material as the second drain electrode 225. The second source electrode 227 may be formed by a same process as the second drain electrode 225. For example, the second source electrode 227 may be formed simultaneously with the second drain electrode 225. The second source electrode 227 may be electrically connected to the second source region of the second semiconductor pattern 221. The second source electrode 227 may be insulated from the second gate electrode 223. The second source electrode 227 may be spaced apart from the second drain electrode 225.

The storage capacitor Cst of each pixel area PA may maintain a signal applied to the second gate electrode 223 of the corresponding pixel area PA for one frame. For example, the storage capacitor Cst of each pixel area PA may be electrically connected between the second gate electrode 223 and the second source electrode 227 of the corresponding pixel area PA. The storage capacitor Cst of each pixel area PA may have a stacked structure of capacitor electrodes. For example, the storage capacitor Cst of each pixel area PA may include a first capacitor electrode electrically connected to the second gate electrode 223 of the corresponding pixel area PA and a second capacitor electrode electrically connected to the second source electrode 227 of the corresponding pixel area PA.

The storage capacitor Cst of each pixel area PA may be formed by using a process of forming the first thin film transistor TR1 and the second thin film transistor TR2 of the corresponding pixel area PA. For example, the first capacitor electrode of each pixel area PA may be disposed on a same layer as the second gate electrode 223 of the corresponding pixel area PA, and the second capacitor electrode of each pixel area PA may be disposed on a same layer as the second source electrode 227 of the corresponding pixel area PA. The first capacitor electrode of each pixel area PA may include a same material as the second gate electrode 223 of the corresponding pixel area PA, and the second capacitor electrode of each pixel area PA may include a same material as the second source electrode 227 of the corresponding pixel area PA. The first capacitor electrode of each pixel area PA may be formed by a same process as the second gate electrode 223 of the corresponding pixel area PA, and the second capacitor electrode of each pixel area PA may be formed by a same process as the second source electrode 227 of the corresponding pixel area PA. For example, the first capacitor electrode of each pixel area PA may be formed simultaneously with the second gate electrode 223 of the corresponding pixel area PA, and the second capacitor electrode of each pixel area PA may be formed simultaneously with the second source electrode 227 of the corresponding pixel area PA.

The driving circuit DC and the light-emitting device of each pixel area PA may be supported by a device substrate 100. For example, the first thin film transistor TR1, the second thin film transistor TR2 and the storage capacitor Cst of each pixel area PA may be disposed on the corresponding pixel area PA of the device substrate 100. The device substrate 100 may include an insulating material. For example, the device substrate 100 may include glass or plastic.

A plurality of insulating layers 110, 120, 130, 140, 150 and 160 for preventing unnecessary electrical connection in each pixel area PA may be disposed on the device substrate 100. For example, a buffer insulating layer 110, a gate insulating layer 120, a interlayer insulating layer 130, a device passivation layer 140, a planarization layer 150 and a bank insulating layer 160 may be disposed on the device substrate 100.

The buffer insulating layer 110 may be disposed close to the device substrate 100. The buffer insulating layer 110 may prevent pollution due to the device substrate 100 in a process of forming the driving circuit DC in each pixel area PA. For example, an upper surface of the device substrate 100 toward the driving circuit DC of each pixel area PA may be completely covered by the buffer insulating layer 110. The driving circuit DC of each pixel area PA may be disposed on the buffer insulating layer 110. The buffer insulating layer 110 may include an insulating material. For example, the buffer insulating layer 110 may include an inorganic insulating material, such as silicon oxide (SiOx) and silicon nitride (SiNx). The buffer insulating layer 110 may have a multi-layer structure. For example, the buffer insulating layer 110 may have a structure, in which an inorganic insulating layer made of silicon oxide (SiOx) and an inorganic insulating layer made of silicon nitride (SiNx) are alternately stacked.

The gate insulating layer 120 may be disposed on the buffer insulating layer 110. The first gate electrode of the each pixel area PA may be insulated from the first semiconductor pattern of the corresponding pixel area PA by the gate insulating layer 120. The second gate electrode 223 of each pixel area PA may be insulated from the second semiconductor pattern 221 of the corresponding pixel area PA by the gate insulating layer 120. For example, the gate insulating layer 120 may cover the first semiconductor pattern and the second semiconductor pattern 221 of each pixel area PA. The first gate electrode and the second gate electrode 223 of each pixel area PA may be disposed on the gate insulating layer 120. The gate insulating layer 120 may include an insulating material. For example, the gate insulating layer 120 may include an inorganic insulating material, such as silicon oxide (SiOx) and silicon nitride (SiNx).

The interlayer insulating layer 130 may be disposed on the gate insulating layer 120. The first drain electrode and the first source electrode of each pixel area PA may be insulated from the first gate electrode of the corresponding pixel area PA by the interlayer insulating layer. The second drain electrode 225 and the second source electrode 227 of each pixel area PA may be insulated from the second gate electrode 223 of the corresponding pixel area PA by the interlayer insulating layer. For example, the interlayer insulating layer 130 may cover the first gate electrode and the second gate electrode 223 of each pixel area PA. The first drain electrode, the first source electrode, the second drain electrode 225 and the second source electrode 227 of each pixel area PA may be disposed on the interlayer insulating layer 130. The interlayer insulating layer 130 may include an insulating material. For example, the interlayer insulating layer 130 may include an inorganic insulating material.

The device passivation layer 140 may be disposed on the interlayer insulating layer 130. The device passivation layer 140 may prevent damage of the driving circuit DC in each pixel area PA due to external impact and moisture. For example, the driving circuit DC of each pixel area PA may be covered by the device passivation layer 140. The device passivation layer 140 may cover the first drain electrode, the first source electrode, the second drain electrode 225 and the second source electrode 227 of each pixel area PA. The device passivation layer 140 may include an insulating material. For example, the device passivation layer 140 may be an inorganic insulating material.

The planarization layer 150 may be disposed on the device passivation layer 140. The planarization layer 150 may remove a thickness difference due to the pixel driving circuit DC of each pixel area PA. For example, an upper surface of the planarization layer 150 opposite to the device substrate 100 may be a flat surface. The upper surface of the planarization layer 150 may be parallel to the upper surface of the device substrate 100. The planarization layer 150 may include an insulating material. The planarization layer 150 may include a material different from the device passivation layer 140. The planarization layer 150 may include a material having a high fluidity. For example, the planarization layer 150 may include an organic insulating material.

The light-emitting device 300 of each pixel area PA may be disposed on the planarization layer 150. The light-emitting device 300 of each pixel area PA may emit light displaying a specific color. For example, the light-emitting device 300 of each pixel area PA may include a first electrode 310, a light-emitting unit 320 and a second electrode 330, which are sequentially stacked on the planarization layer 150 of the corresponding pixel area PA.

The first electrode 310 may include a conductive material. The first electrode 310 may include a material having a high reflectance. For example, the first electrode 310 may be a metal, such as aluminum (Al) and silver (Ag). The first electrode 310 may have a multi-layer structure. For example, the first electrode 310 may have a structure in which a reflective electrode made of a metal is disposed between transparent electrodes made of a transparent conductive material, such as ITO and IZO.

The light-emitting unit 320 may generate light having luminance corresponding to a voltage difference between the first electrode 310 and the second electrode 330. For example, the light-emitting layer 320 may include an emission material layer (EML). The emission material layer (EML) may include an emission material. The emission material may include an organic material, an inorganic material or a hybrid material. For example, the display apparatus according to the embodiment of the present disclosure may be an organic light-emitting display apparatus including an organic emission material.

A plurality of emission material layers (EML) may be disposed in the light-emitting unit 320. For example, the light-emitting unit 320 may include a first emission stack 321, a charge generation layer 322 and a second emission stack 323, which are sequentially stacked. Each of the first emission stack 321 and the second emission stack 322 may include at least one emission material layer (EML). The charge generation layer 322 may supply holes or electrons to the first emission stack 321 and the second emission stack 323. For example, the charge generation layer 322 may have a stacked structure of a n-type charge generating layer 322n and a p-type charge generating layer 322p. Each of the first emission stack 321 and the second emission stack 323 may emit light.

Light generated by the second emission stack 323 may display a different color from light generated by the first emission stack 321. For example, the emission material layer (EML) of the second emission stack 323 may include a different material from the emission material layer (EML) of the first emission stack 321. A color represented by light generated by the light-emitting unit 320 may be a color represented by overlapping the light generated by the first emission stack 321 and the light generated by the second emission stack 323.

Each of the first emission stack 321 and the second emission stack 323 may further include at least one functional layer to smoothly supply holes or electrons. The functional layer may be one of a hole injection layer (HIL), a hole transport layer (HTL), an electron transport layer (ETL) and an electron injection layer (EIL). For example, the first emission stack 321 may include a hole injection layer 321hi, a first hole transport layer 321ht, a first emission material layer 321em and a first electron transport layer 321et, and the second emission stack 323 may include a second hole transport layer 323ht, a second emission material layer 323em, a second electron transport layer 323et and an electron injection layer 323ei. The first electrode 310 may function as an anode electrode, and the second electrode 330 may function as a cathode electrode. For example, a work-function of the first electrode 310 may be higher than a work-function of the second electrode 330. The p-type charge generating layer 322p of the charge generation layer 322 may be disposed between the n-type charge generating layer 322n of the charge generation layer 322 and the second hole transport layer 323ht of the second emission stack 323.

The second electrode 330 may include a conductive material. The second electrode 330 may include a different material from the first electrode 310. A transmittance of the second electrode 330 may be higher than a transmittance of the first electrode 310. For example, the second electrode 330 may be a transparent electrode made of a transparent conductive material, such as ITO and IZO, or a translucent electrode in which metals such as Ag and Mg are thinly formed. Thus, in the display apparatus according to the embodiment of the present disclosure, the light generated by the light-emitting unit 320 may be emitted outside through the second electrode 330.

The light-emitting device 300 of each pixel area PA may be electrically connected to the second thin film transistor TR2 of the driving circuit DC in the corresponding pixel area PA. For example, the first electrode 310 of each pixel area PA may be in direct contact with the second source electrode 227 of the corresponding pixel area PA by penetrating the planarization layer 150. The first electrode 310 of each pixel area PA may include a portion being in direct contact with the upper surface of the planarization layer 150. For example, the light-emitting unit 320 and the second electrode 330 of each pixel area PA may be stacked on a portion of the corresponding first electrode 310, which is in direct contact with the upper surface of the planarization layer 150.

The bank insulating layer 160 may be disposed on the planarization layer 150. The bank insulating layer 160 may define an emission area R-EA, G-EA and B-EA in each pixel area PA. An area between the emission areas R-EA, G-EA and B-EA may be defined as a non-emission area NEA. For example, the bank insulating layer 160 may overlap the non-emission area NEA. Each of the emission areas R-EA, G-EA and B-EA may be surrounded by the non-emission area NEA.

The first electrode 310 of each pixel area PA may be partially exposed by the bank insulating layer 160. For example, an edge of the first electrode 310 in each pixel area PA may be covered by the bank insulating layer 160. The bank insulating layer 160 may include an insulating material. For example, the bank insulating layer 160 may be an organic insulating material. The bank insulating layer 160 may include a different material from the planarization layer 150. Thus, in the display apparatus according to the embodiment of the present disclosure, the first electrode 310 of each pixel area PA may be insulated from the first electrode 310 of adjacent pixel area PA by the bank insulating layer 160.

A portion of the first electrode 310 in each pixel area PA exposed by the bank insulating layer 160 may overlap the emission area R-EA, G-EA and B-EA of the corresponding pixel area PA. A portion of the first electrode 310 overlapping with the emission area R-EA, G-EA and B-EA in each pixel area PA may be in direct contact with the upper surface of the planarization layer 150. For example, the light-emitting unit 320 and the second electrode 330 of each pixel area PA may be stacked on the emission area R-EA, G-EA and B-EA of the corresponding pixel area PA defined by the bank insulating layer 160. Thus, in the display apparatus according to the embodiment of the present disclosure, luminance deviation due to the generating location of the light emitted from the emission area R-EA, G-EA and B-EA of each pixel area PA may be prevented.

A voltage applied to the second electrode 330 of each pixel area PA may be a same as a voltage applied to the second electrode 330 of adjacent pixel area PA. For example, the second electrode 330 of each pixel area PA may be electrically connected to the second electrode 330 of adjacent pixel area PA. The second electrode 330 of each pixel area PA may include a same material as the second electrode 330 of adjacent pixel area PA. The second electrode 330 of each pixel area PA may be formed by a same process as the second electrode 330 of adjacent pixel area PA. For example, the second electrode 330 of each pixel area PA may be formed simultaneously with the second electrode 330 of adjacent pixel area PA. The second electrode 330 of each pixel area PA may be in direct contact with the second electrode 330 of adjacent pixel area PA. For example, the second electrode 330 of each pixel area PA may extend onto the bank insulating layer 160. Thus, in the display apparatus according to the embodiment of the present disclosure, a process of forming the second electrode 330 in each pixel area PA may be simplified. And, in the display apparatus according to the embodiment of the present disclosure, the luminance of the light emitted from the light-emitting device 300 of each pixel area PA may be adjusted by the data signal applied to the driving circuit DC of the corresponding pixel area PA.

Light emitted from the light-emitting device 300 of each pixel area PA may display a same color as light emitted from the light-emitting device 300 of adjacent pixel area PA. For example, the light emitted from the light-emitting device 300 of each pixel area PA may be white light. The light-emitting unit 320 of each pixel area PA may have a same structure as the light-emitting unit 320 of adjacent pixel area PA. The light-emitting unit 320 of each pixel area PA may be formed by a same process as the light-emitting unit 320 of adjacent pixel area PA. For example, the first emission stack 321, the charge generation layer 322 and the second emission stack 323 of each pixel area PA may be formed simultaneously with the first emission stack 321, the charge generation layer 322 and the second emission stack 323 of adjacent each pixel area PA, respectively. The first emission stack 321, the charge generation layer 322 and the second emission stack 323 of each pixel area PA may be in direct contact with the first emission stack 321, the charge generation layer 322 and the second emission stack 323 of adjacent each pixel area PA, respectively. For example, the first emission stack 321, the charge generation layer 322 and the second emission stack 323 may be stacked on the bank insulating layer 160.

A portion of the charge generation layer 322 on the bank insulating layer 160 may have a greater resistance than a portion of the charge generation layer 322 overlapping with one of emission areas R-EA, G-EA and B-EA. For example, the charge generation layer 322 may include a high-resistance region HA overlapping with the bank insulating layer 160. The high-resistance region HA of the charge generation layer 322 may extend along the bank insulating layer 160. For example, the high-resistance region HA of the charge generation layer 322 may surround each of the emission areas R-EA, G-EA and B-EA. Generally, current may flow through a region of a relative low resistance. Thus, in the display apparatus according to the embodiment of the present disclosure, the driving current applied to the first electrode 310 of each emission area R-EA, G-EA and B-EA may not flow the outside of the corresponding emission area R-EA, G-EA and B-EA by the high-resistance region HA of the charge generation layer 322. Therefore, in the display apparatus according to the embodiment of the present disclosure, leakage current through the charge generation layer 322 may be prevented.

In the display apparatus according to the embodiment of the present disclosure, a resistance between the first emission stack 321 and the second electrode 330 on the bank insulating layer 160 may be greater than a resistance between the first emission stack 321 and the second electrode 330 on each emission area R-EA, G-EA and B-EA due to the high-resistance region HA of the charge generation layer 322. Thus, in the display apparatus according to the embodiment of the present disclosure, the driving current applied to the first electrode 310 of each emission area R-EA, G-EA and B-EA may flow to the second electrode 330 only through a portion of the charge generation layer 322 overlapping with the corresponding emission area R-EA, G-EA and B-EA. Therefore, in the display apparatus according to the embodiment of the present disclosure, efficiency of the light-emitting device 300 in each pixel area PA may be improved.

The high-resistance region HA of the charge generation layer 322 may be formed in various ways. For example, a step of forming the high-resistance region HA of the charge generation layer 322 may include a step of hydrophobizing a portion of the charge generation layer 322 overlapping with the bank insulating layer 160 using a selective plasma process. The selective plasma process may include a plasma printing process. For example, a step of forming the charge generation layer 322 including the high-resistance region HA may include a step of forming the n-type charge generating layer 322n on the first emission stack 321, a step of forming a surface treatment portion SA having hydrophobicity by treating a portion of the n-type charge generating layer 322n overlapping with the bank insulating layer 160 using CF4 or SF6 plasma, and a step of forming the p-type charge generating layer 322p on the n-type charge generating layer 322n including the surface treatment portion SA. The n-type charge generating layer 322n may be formed of an organic material. Thus, in the display apparatus according to the embodiment of the present disclosure, the surface treatment portion SA having hydrophobicity may be formed by replacing an end group of carbon (C) with fluorine at an upper portion of the n-type charge generation layer 322n toward the p-type charge generation layer 322p. That is, in the display apparatus according to the embodiment of the present disclosure, surface energy of the surface treatment portion SA may be reduced due to an end group of carbon (C) being substituted with fluorine. Therefore, in the display apparatus according to the embodiment of the present disclosure, a resistance of a portion of the n-type charge generating layer 322n overlapping with the bank insulating layer 160 may be increased due to the surface treatment portion SA having hydrophobicity.

And, in the display apparatus according to the embodiment of the present disclosure, a surface tension of the surface treatment portion SA may be changed by carbon (C) in which an end group is substituted with fluorine. Thus, in the display apparatus according to the embodiment of the present disclosure, the p-type charge generating layer 322p formed on the n-type charge generating layer 322n may have a relative thin thickness on the surface treatment portion SA. For example, the p-type charge generating layer 322p overlapping with the bank insulating layer 160 may include a portion having a smaller thickness than the p-type charge generating layer 322p overlapping with each emission area R-EA, G-EA and B-EA. Generally, a resistance of a layer may be inversely proportional to a thickness of the corresponding layer. That is, in the display apparatus according to the embodiment of the present disclosure, a portion of the p-type charge generating layer 322p formed to have a relative small thickness due to the surface treatment portion SA may have a relative large resistance. The surface treatment portion SA may be formed at an upper portion of the n-type charge generating layer 322n toward the p-type charge generating layer 322p. A portion of the n-type charge generating layer 322n including the surface treatment portion SA and a portion of the p-type charge generating layer 322p formed to have relative thin thickness by the surface treatment portion SA may be defined as a high-resistance region HA. Therefore, in the display apparatus according to the embodiment of the present disclosure, a process of forming the high-resistance region HA in a portion of the charge generation layer 322 overlapping with the bank insulating layer 160 may be simplified.

In the display apparatus according to the embodiment of the present disclosure, the bank insulating layer 160 may include a light-absorbing material. The light-absorbing material may be a black dye, such as carbon black. Thus, in the display apparatus according to the embodiment of the present disclosure, light irradiated to form the surface treatment portion SA of the charge generation layer 322 may be absorbed by the bank insulating layer 160. That is, in the display apparatus according to the embodiment of the present disclosure, the reflection of the light irradiated to form the surface treatment portion SA of the charge generation layer 322 due to the signal wiring GL, DL and PL, the first electrode 310 of each emission area R-EA, G-EA and B-EA, and/or electrodes of the driving circuit DC in each R-EA, G-EA and B-EA may be prevented. Therefore, in the display apparatus according to the embodiment of the present disclosure, deterioration in efficiency of each emission area R-EA, G-EA and B-EA due to a process of forming the surface treatment portion SA of the charge generation layer 322 may be prevented.

An encapsulation structure 400 may be disposed on the light-emitting device 300 of each pixel area PA. The encapsulation structure 400 may prevent damage of the light-emitting devices 300 due to external moisture and impact. The encapsulation structure 400 may have a multi-layer structure. For example, the encapsulation structure 400 may include a first encapsulating layer 410, a second encapsulating layer 420 and a third encapsulating layer 430, which are sequentially stacked. The first encapsulating layer 410, the second encapsulating layer 420 and the third encapsulating layer 430 may include an insulating material. The second encapsulating layer 420 may include a different material from the first encapsulating layer 410 and the third encapsulating layer 430. For example, the first encapsulating layer 410 and the third encapsulating layer 430 may be an inorganic insulating layer including an inorganic insulating material, and the second encapsulating layer 420 may be an organic insulating layer including an organic insulating material. A thickness difference due to the light-emitting device 300 of each pixel area PA may be removed by the second encapsulating layer 420. For example, an upper surface of the encapsulation structure 400 opposite to the device substrate 100 may be a flat surface. The upper surface of the encapsulation structure 400 may be parallel to the upper surface of the device substrate 100. Thus, in the display apparatus according to the embodiment of the present disclosure, the damage of the light-emitting device 300 in each pixel area PA due to the external moisture and impact may be effectively prevented.

Each of the pixel area PA may realize a different color from adjacent pixel area PA. For example, the emission area R-EA, G-EA and B-EA of each pixel area PA may be one of a red emission area R-EA realizing red color, a green emission area G-EA realizing green color, and a blue emission area B-EA realizing blue color. A color filter 500R, 500G and 500B to realize a color of each emission area R-EA, G-EA and B-EA may be disposed on the emission area R-EA, G-EA and B-EA of the corresponding pixel area PA. The color filter 500R, 500G and 500B of each pixel area PA may overlap the emission area R-EA, G-EA and B-EA of the corresponding pixel area PA. For example, a red color filter 500R overlapping with the red emission area R-EA, a green color filter 500G overlapping with the green emission area G-EA and a blue color filter 500B overlapping with the blue emission area B-EA may be disposed on the encapsulation structure 400. The color filter 500R, 500G and 500B of each emission area R-EA, G-EA and B-EA may have a greater size than the corresponding emission area R-EA, G-EA and B-EA. Thus, in the display apparatus according to the embodiment of the present disclosure, the light emitted from the light-emitting device 300 of each pixel area PA must pass through the color filter 500R, 500G and 500B of the corresponding pixel area PA. Therefore, in the display apparatus according to the embodiment of the present disclosure, deterioration in quality of the image due to light which not pass through the color filters 500R, 500G and 500B may be prevented.

A filter passivation layer 600 may be disposed on the color filter 500R, 500G and 500B of each pixel area PA. The filter passivation layer 600 may prevent damage of the color filters 500R, 500G and 500B due to the external impact and moisture. For example, the color filter 500R, 500G and 500B of each pixel area PA may be completely covered by the filter passivation layer 600. The filter passivation layer 600 may include an insulating material. For example, the filter passivation layer 600 may include at least one of an inorganic insulating material and an organic insulating material. The filter passivation layer 600 may include a multi-layer structure. For example, the filter passivation layer 600 may have a structure in which an inorganic insulating layer made of an inorganic insulating material is formed on an organic insulating layer made of an organic insulating material. A thickness difference due to the color filters 500R, 500G and 500B may be removed by the filter passivation layer 600. Thus, in the display apparatus according to the embodiment of the present disclosure, the damage of the color filters 500R, 500G and 500B in each pixel area PA due to the external impact and moisture may be effectively prevented.

Accordingly, the display apparatus according to the embodiment of the present disclosure may include the light-emitting devices 300 at each emission area R-EA, G-EA and B-EA, and the bank insulating layer 160 at the non-emission area NEA, wherein the light-emitting unit 320 of each light-emitting device 300 may include the charge generation layer 322 extending onto the bank insulating layer 160, and wherein a portion of the charge generation layer 322 disposed on the bank insulating layer 160 may include the high-resistance region HA having relative high resistance. Thus, in the display apparatus according to the embodiment of the present disclosure, the driving current applied to the first electrode 310 of each emission area R-EA, G-EA and B-EA may not flow to adjacent emission area R-EA, G-EA and B-EA. That is, in the display apparatus according to the embodiment of the present disclosure, leakage current may be prevented by the high-resistance region HA of the charge generation layer 322. Therefore, in the display apparatus according to the embodiment of the present disclosure, the generation and the emission of light in an unintended area due to the current leaked may be prevented. And, in the display apparatus according to the embodiment of the present disclosure, emission efficiency of each emission area R-EA, G-EA and B-EA may be improved.

In the display apparatus according to the embodiment of the present disclosure, the high-resistance region HA of the charge generation layer 322 may be formed using a selectivity plasma process. Thus, in the display apparatus according to the embodiment of the present disclosure, a process of forming the high-resistance region HA of the charge generation layer 322 may be simplified. Therefore, in the display apparatus according to the embodiment of the present disclosure, deterioration of a process efficiency due to form the high-resistance region HA in a portion of the charge generation layer 322 overlapping with the bank insulating layer 160 may be reduced.

The display apparatus according to the embodiment of the present disclosure is described that the driving circuit DC of each pixel area PA consists of the first thin film transistor TR1, the second thin film transistor TR2 and the storage capacitor Cst. However, in the display apparatus according to another embodiment of the present disclosure, the driving circuit DC of each pixel area PA may include a driving thin film transistor and at least one switching thin film transistor. For example, in the display apparatus according to another embodiment of the present disclosure, the driving circuit DC of each pixel area PA may further include a third thin film transistor for initializing the storage capacitor Cst of the corresponding pixel area PA according to the gate signal. The third thin film transistor of each pixel area PA may include a third semiconductor pattern, a third gate electrode, a third drain electrode and a third source electrode. The third semiconductor pattern of each pixel area PA may include a semiconductor material. The third gate electrode of each pixel area PA may be electrically connected to the corresponding gate line GL. The third drain electrode of each pixel area PA may be electrically connected to an initial line applying an initial signal. The third source electrode of each pixel area PA may be electrically connected to the storage capacitor Cst of the corresponding pixel area PA. Thus, in the display apparatus according to another embodiment of the present disclosure, the degree of freedom in configuration of each driving circuit DC may be improved.

In the display apparatus according to the embodiment of the present disclosure, the location and the electric connection of the first drain electrode, the first source electrode, the second drain electrodes 225 and the second source electrode 227 in each driving circuit DC may vary depending on the configuration of the corresponding driving circuit DC and/or the type of the corresponding thin film transistors TR1 and TR2. For example, in the display apparatus according to another embodiment of the present disclosure, the second gate electrode 223 of each driving circuit DC may be electrically connected to the first drain electrode of the corresponding driving circuit DC. Thus, in the display apparatus according to another embodiment of the present disclosure, the degree of freedom in the configuration of each driving circuit DC and the type of each thin film transistor TR1 and TR2 may be improved.

The display apparatus according to the embodiment of the present disclosure is described that the first electrode 310 of each pixel area PA may have a larger reflectance than the second electrode 330 of the corresponding pixel area PA. However, in the display apparatus according to another embodiment of the present disclosure, the first electrode 310 of each pixel area PA may have a larger transmittance than the second electrode 330 of the corresponding pixel area PA. For example, in the display apparatus according to another embodiment of the present disclosure, the light generated by the light-emitting unit 320 of each pixel area PA may be emitted outside through the corresponding first electrode 310 and the device substrate 100. The driving circuit DC of each pixel area PA may be disposed outside the emission area R-EA, G-EA and B-EA of the corresponding pixel area PA. The color filter 500R, 500G and 500B of each pixel area PA may be disposed between the device substrate 100 and the first electrode 310 of the corresponding pixel area PA. For example, the color filter 500R, 500G and 500B of each pixel area PA may be disposed between the device passivation layer 140 and the planarization layer 150 of the corresponding pixel area PA. A thickness difference due to the color filter 500R, 500G and 500B of each pixel area PA may be removed by the planarization layer 150. Thus, in the display apparatus according to another embodiment of the present disclosure, light leakage due to leakage current may be prevented and efficiency of each light-emitting device 300 may be improved, regardless of the emission direction of the light generated by the light-emitting unit 320 of each pixel area PA.

The display apparatus according to the embodiment of the present disclosure is described that the light generated by the second emission stack 323 of each emission area R-EA, G-EA and B-EA may display a different color from the light generation by the first emission stack 321 of the corresponding emission area R-EA, G-EA and B-EA. However, in the display device according to another embodiment of the present disclosure, the light generated by the second emission stack 323 of each emission area R-EA, G-EA and B-EA may display a same color as the light generation by the first emission stack 321 of the corresponding emission area R-EA, G-EA and B-EA. For example, in the display apparatus according to another embodiment of the present disclosure, the first emission stack 321 and the second emission stack 323 disposed on a red emission area R-EA may emit light displaying red color, the first emission stack 321 and the second emission stack 323 disposed on a green emission area G-EA may emit light displaying green color, and the first emission stack 321 and the second emission stack 323 disposed on a blue emission area B-EA may emit light displaying blue color. Thus, in the display apparatus according to another embodiment of the present disclosure, color reproducibility may be improved.

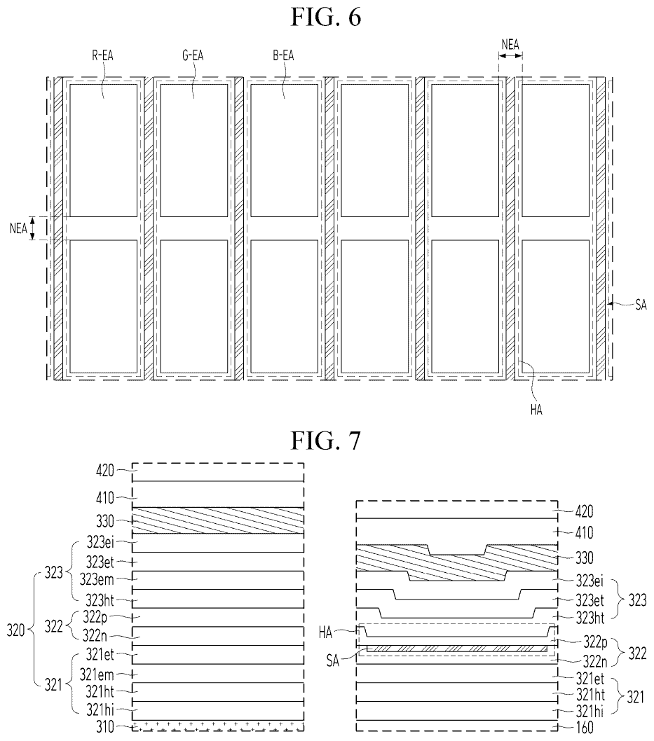

The display apparatus according to the embodiment of the present disclosure is described that the high-resistance region HA of the charge generation layer 322 may have a mesh shape, and each of the emission area R-EA, G-EA and B-EA may be disposed in one of regions defined by the high-resistance region HA. However, in the display device according to another embodiment of the present disclosure, the high-resistance region HA of the charge generation layer 322 may have a shape extending in a direction. For example, in the display apparatus according to another embodiment of the present disclosure, the emission area R-EA, G-EA and B-EA of each pixel area PA may realize a different color from the emission area R-EA, G-EA and B-EA of adjacent pixel area PA in a first direction, the emission area R-EA, G-EA and B-EA of each pixel area PA may realize a same color as the emission area R-EA, G-EA and B-EA of adjacent pixel area PA in a second direction perpendicular to the first direction, and the high-resistance region HA of the charge generation layer 322 may have a shape extending in the second direction, as shown in FIG. 6. For example, in the display apparatus according to another embodiment of the present disclosure, the surface treatment portion SA may be formed only in a portion of the charge generation layer 322 disposed between the emission areas R-EA, G-EA and B-EA, which realize a different colors by the plasma printing process. That is, in the display apparatus according to another embodiment of the present disclosure, the high-resistance region HA of the charge generation layer 322 may not be formed between the emission areas R-EA, G-EA and B-EA, that realize a same color. Thus, in the display apparatus according to another embodiment of the present disclosure, color mixing due to leakage current may be prevented, and a process of forming the high-resistance region HA of the charge generation layer 322 may be further simplified. Therefore, in the display apparatus according to another embodiment of the present disclosure, deterioration of process efficiency may be minimized. And, in the display apparatus according to another embodiment of the present disclosure, damage of each light-emitting device 300 due to plasma used to form the high-resistance region HA of the charge generation layer 322 may be effectively prevented.

The display apparatus according to the embodiment of the present disclosure is described that the emission material layer 321em and 323em of each emission stack 321 and 323 may include a region overlapping with the bank insulating layer 160. However, in the display device according to another embodiment of the present disclosure, the first emission material layer 321em of the first emission stack 321 and the second emission material layer 323em of the second emission stack 323 in each emission area R-EA, G-EA and B-EA may be disposed only in the corresponding emission area R-EA, G-EA and B-EA. For example, in the display apparatus according to another embodiment of the present disclosure, the first electron transport layer 321et may be in direct contact with the first hole transport layer 321ht on the bank insulating layer 160, and the second electron transport layer 323et may be in direct contact with the second hole transport layer 323ht on the bank insulating layer 160, as shown in FIG. 7. Thus, in the display apparatus according to another embodiment of the present disclosure, the emission material layer 321em and 323em of each emission stack 321 and 323 may not be in contact with the high-resistance region HA of the charge generation layer 322. The high-resistance region HA of the charge generation layer 322 may be disposed outside the emission material layer 321em and 323em in each emission stack 321 and 323. For example, the emission material layer 321em and 323em of each emission area may be formed only on the corresponding emission area by an ink-jet process. Therefore, in the display apparatus according to another embodiment of the present disclosure, deterioration of the emission material layer 321em and 323em due to a process of forming the surface treatment portion SA of the charge generation layer 322 may be prevented. That is, in the display apparatus according to another embodiment of the present disclosure, decrease in quality of the image due to a process of forming the surface treatment portion SA of the charge generation layer 322 may be prevented.

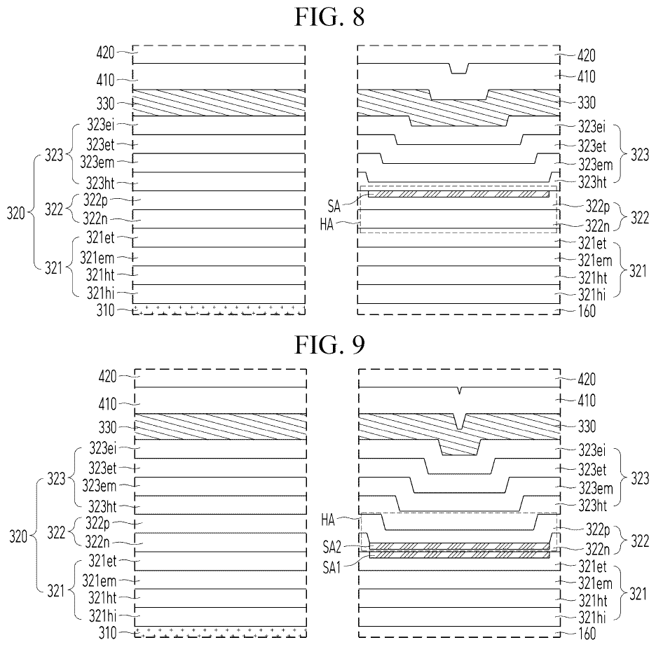

The display apparatus according to the embodiment of the present disclosure is described that the surface treatment portion SA may be formed on a portion of the n-type charge generating layer 322n overlapping with the bank insulating layer 160. However, in the display device according to another embodiment of the present disclosure, the surface treatment portion SA may be formed on a portion of at least one of various layers overlapping with the bank insulating layer 160. For example, in the display apparatus according to another embodiment of the present disclosure, the surface treatment portion SA may be formed on a portion of the p-type charge generating layer 322p overlapping with the bank insulating layer 160, as shown in FIG. 8. The p-type charge generating layer 322p may be formed of an organic insulating material. Thus, in the display apparatus according to another embodiment of the present disclosure, a portion of the p-type charge generating layer 322p overlapping with the bank insulating layer 160 may have a relative high resistance. That is, in the display apparatus according to another embodiment of the present disclosure, the charge generating layer 322 may include the high-resistance region HA overlapping with the bank insulating layer 160 by the p-type charge generating layer 322p including the surface treatment portion SA. The surface treatment SA may be disposed on an upper portion of the p-type charge generating layer 322p toward the second hole transport layer 323ht. The second hole transport layer 323ht may include a portion being in direct contact with the surface treatment portion SA. A portion of the second hole transport layer 323ht overlapping with the surface treatment portion SA may have a relative thin thickness. Therefore, in the display apparatus according to another embodiment of the present disclosure, the degree of freedom in location of the surface treatment portion SA may be improved.

In the display apparatus according to another embodiment of the present disclosure, a portion of the n-type charge generating layer 322n in the high-resistance region HA may have a relative thin thickness. For example, in the display apparatus according to another embodiment of the present disclosure, a first surface treatment portion SA1 may be formed at an upper portion of the first electron transport layer 321et overlapping with the bank insulating layer 160, and a second surface treatment portion SA2 may be formed at an upper portion of the n-type charge generating layer 322n overlapping with the bank insulating layer 160, as shown in FIG. 9. The first electron transport layer 321et and the n-type charge generating layer 322n may be formed of an organic material. The second surface treatment portion SA2 may overlap the first surface treatment portion SA1. The first surface treatment portion SA1 may be disposed outside the high-resistance region HA of the charge generation layer 322. For example, the high-resistance region HA of the charge generation layer 322 may include the second surface treatment portion SA2. Thus, in the display apparatus according to another embodiment of the present disclosure, a resistance of the high-resistance region HA of the charge generation layer 322 may be effectively increased. That is, in the display apparatus according to another embodiment of the present disclosure, resistance difference between the high-resistance region HA of the charge generation layer 322 and a portion of the charge generation layer 322 overlapping with the emission area may be increased. Therefore, in the display apparatus according to another embodiment of the present disclosure, leakage current may be effectively prevented, and efficiency of each emission area may be greatly increased.

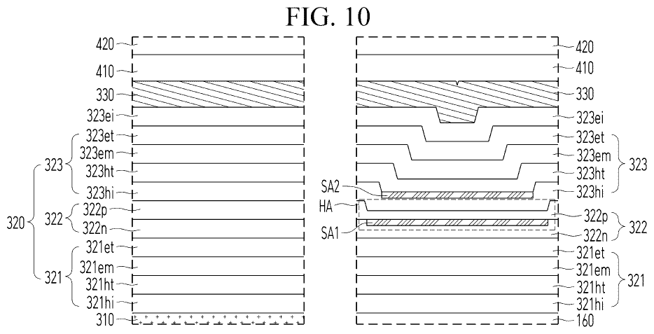

In the display apparatus according to another embodiment of the present disclosure, a resistance between the first emission stack 321 and the second electrode 330 on the bank insulating layer 160 may have a greatly difference from a resistance between the first emission stack 321 and the second electrode 330 in the emission area R-EA, G-EA and B-EA. For example, in the display apparatus according to another embodiment of the present disclosure, the second emission stack 323 may include a second hole injection layer 323hi between the p-type charge generating layer 322p and the second hole transport layer 323ht, the first surface treatment portion SA1 may be formed at a portion of the n-type charge generating layer 322n overlapping with the bank insulating layer 160, and the second surface treatment portion SA2 may be formed at a portion of the second hole injection layer 323hi overlapping with the bank insulating layer 160, as shown in FIG. 10. The n-type charge generating layer 322n and the second hole injection layer 323hi may be formed of an organic material. Thus, in the display apparatus according to another embodiment of the present disclosure, a resistance between the first emission stack 321 and the second electrode 330 on the bank insulating layer 160 may be greatly increased due to the second surface treatment portion SA2. Therefore, in the display apparatus according to another embodiment of the present disclosure, light leakage due to leakage current may be effectively prevented, and efficiency of each emission area may be greatly improved.

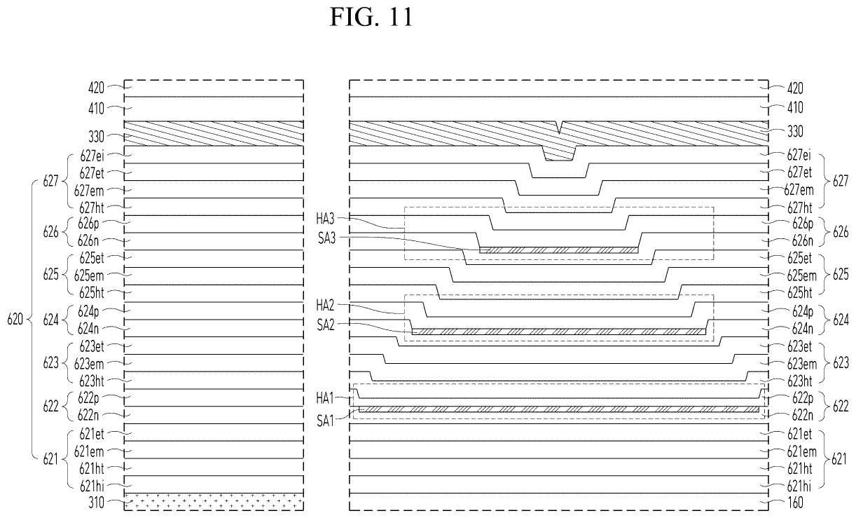

The display apparatus according to the embodiment of the present disclosure is described that the light-emitting unit 320 of each emission area R-EA, G-EA and B-EA may include the charge generation layer 322 between the first emission stack 321 and the second emission stack 323. However, in the display apparatus according to another embodiment of the present disclosure, the light-emitting unit 320 of each emission area R-EA, G-EA and B-EA may include a plurality of emission stacks 321 and 323, and at least one charge generation layer 322. For example, in the display apparatus according to another embodiment of the present disclosure, the light-emitting unit 320 of each emission area may include a first emission stack 621, a first charge generation layer 622, a second emission stack 623, a second charge generation layer 624, a third emission stack 625, a third charge generation layer 626 and a fourth emission stack 627, which are sequentially stacked on the first electrode 310 of the corresponding emission area, as shown in FIG. 11. The second electrode 330 of each emission area may be disposed on the fourth emission stack 627 of the corresponding emission area.

Each of the emission stacks 621, 623, 625 and 627 may include at least one emission material layer 621em, 623em, 625em and 627em. For example, each of the emission stacks 621, 623, 625 and 627 may include a single emission material layer 621em, 623em, 625em and 627em. The first emission stack 621 may include a hole injection layer 621hi, a first hole transport layer 621ht, a first emission material layer 621em and a first electron transport layer 621et. The second emission stack 623 may include a second hole transport layer 623ht, a second emission material layer 623em, and a second electron transport layer 623et. The third emission stack 625 may include a third hole transport layer 625ht, a third emission material layer 625em and a third electron transport layer 625et. The fourth emission stack 627 may include a fourth hole transport layer 627ht, a fourth emission material layer 627em, a fourth electron transport layer 627et, and an electron injection layer 627ei.

Each of the charge generation layers 622, 624 and 626 may have a stacked structure of a n-type charge generating layer 622n, 624n and 626n and a p-type charge generating layer 622p, 624p and 626p. For example, the p-type charge generating layer 622p, 624p and 626p of each charge generation layer 622, 624 and 626 may be disposed on the n-type charge generating layer 622n, 624n and 626n of the corresponding charge generation layer 622, 624 and 626. A portion of each charge generation layer 622, 624 and 626 overlapping with the bank insulating layer 160 may include a high-resistance region HA1, HA2 and HA3. For example, a first surface treatment portion SA1 may be formed in the n-type charge generating layer 622n of the first charge generation layer 622, a second surface treatment portion SA2 may be formed in the n-type charge generating layer 624n of the second charge generation layer 624, and a third surface treatment portion SA3 may be formed in the n-type charge generating layer 626n of the third charge generation layer 626. A first high-resistance region HA1 of the first charge generation layer 622 may include the first surface treatment portion SA1, a second high-resistance region HA2 of the second charge generation layer 624 may include the second surface treatment portion SA2, and a third high-resistance region HA3 of the third charge generation layer 626 may include the third surface treatment portion SA3. The surface treatment portion SA1, SA2 and SA3 of each charge generation layer 622, 624 and 626 may be formed on a flat portion of the corresponding n-type charge generating layer 622n, 624n and 626n. For example, a horizontal width of the second high-resistance region HA2 may be smaller than a horizontal width of the first high-resistance region HA1, and a horizontal width of the third high-resistance region HA3 may be smaller than the horizontal width of the second high-resistance region HA2. Thus, in the display apparatus according to another embodiment of the present disclosure, light may not be generated or emitted in a portion of the light-emitting unit 320 overlapping with the bank insulating layer 160, regardless of the configuration of the light-emitting unit 320 in each light emitting area. And, in the display apparatus according to another embodiment of the present disclosure, leakage current through at least one charge generation layer 622, 624 and 626 covering the bank insulating layer 160 may be prevented. Therefore, in the display apparatus according to another embodiment of the present disclosure, the degree of freedom in configuration of the light-emitting unit 320 in each emission area may be improved.

In the display apparatus according to another embodiment of the present disclosure, at least two of the emission material layers 621em, 623em, 625em and 627em of the emission stacks 621, 623, 625 and 627 in each emission area may include a same material. For example, in the display apparatus according to another embodiment of the present disclosure, the first emission stack 621, the second emission stack 623, the third emission stack 625 and the fourth emission stack 627 may be stacked on each emission area, the first emission material layer 621em of the first emission stack 621 and the fourth emission material layer 627em of the fourth emission stack 627 may include blue emission material, the second emission material layer 623em of the second emission stack 623 may include red emission material, and the third emission material layer 625em of the third emission stack 625 may include green emission material. Thus, in the display apparatus according to another embodiment of the present disclosure, color sense of white light generated by the light-emitting unit 620 in each emission area may be improved.

The display apparatus according to the embodiment of the present disclosure is described that each of the emission stacks 321 and 323 may include a single emission material layer 321em and 323em. However, in the display apparatus according to another embodiment of the present disclosure, at least one of the emission stacks 321 and 323 in each emission area R-EA, G-EA and B-EA may include a plurality of emission material layers 321em and 323em. For example, in the display apparatus according to another embodiment of the present disclosure, the light-emitting unit of each emission area may include a first emission stack including blue emission material layer, a second emission stack including green emission material layer and red emission material layer, a third emission stack including blue emission material layer, a first charge generation layer between the first emission stack and the second emission stack, and a second charge generation layer between the second emission stack and the third emission stack. Thus, in the display apparatus according to another embodiment of the present disclosure, the degree of freedom in configuration of the light-emitting unit disposed in each emission area may be improved.

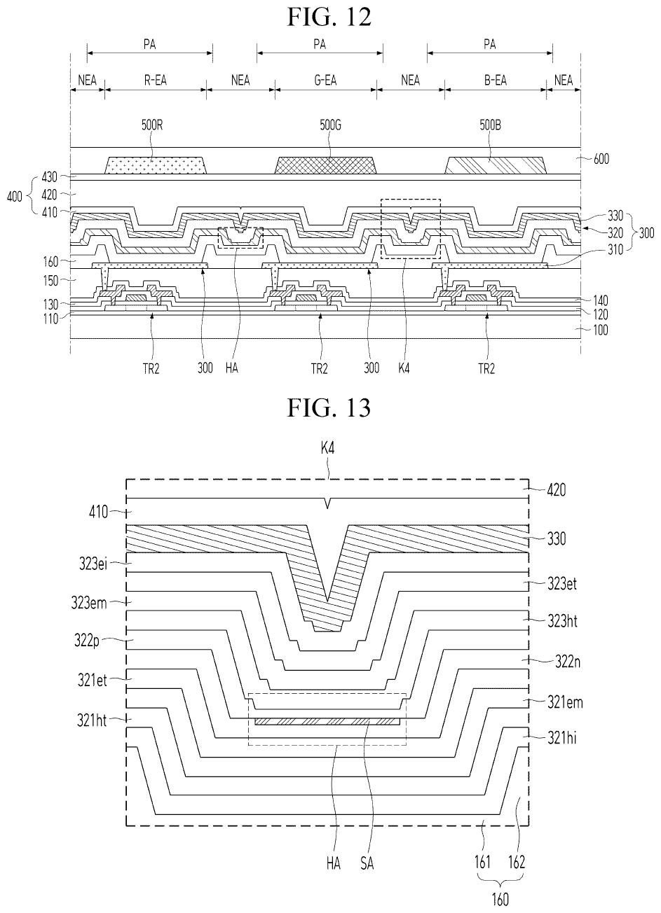

In the display apparatus according to another embodiment of the present disclosure, the bank insulating layer 160 may have various shapes. For example, in the display apparatus according to another embodiment of the present disclosure, the bank insulating layer 160 may include a first bank region 161 and a second bank region 162, as shown in FIGS. 12 and 13. A thickness of the second bank region 162 may be larger than a thickness of the first bank region 161. The second bank region 162 may be disposed close to the emission areas R-EA, G-EA and B-EA. For example, an edge of the first electrode 310 in each emission area R-EA, G-EA and B-EA may be covered by the second bank region 162. The second bank region 162 may be disposed between the first bank region 161 and each emission area R-EA, G-EA and B-EA. Thus, in the display apparatus according to another embodiment of the present disclosure, a concave groove by a difference in thickness between the first bank region 161 and the second bank region 162 may be formed at an upper portion of the bank insulating layer 160.

The surface treatment portion SA of the n-type charge generating layer 322n may be disposed on the first bank region 161. The first bank region 161 may overlap a portion of the p-type charge generating layer 322p having a relative thin thickness. For example, the high-resistance region HA of the charge generation layer 322n and 322p may overlap the first bank region 161. A resistance between the first electron transport layer 321et and the second electrode 330 on the first bank region 161 may be larger than a resistance between the first electron transport layer 321et and the second electrode 330 on the second bank region 162. For example, the resistance between the first electron transport layer 321et and the second electrode 330 on the second bank region 162 may be a same as a resistance between the first electron transport layer 321et and the second electrode 330 on each emission area R-EA, G-EA and B-EA. Thus, in the display apparatus according to another embodiment of the present disclosure, the second bank region 162 may not be affected by a process of forming the surface treatment portion SA of the charge generation layer 322n and 322p. For example, in the display apparatus according to another embodiment of the present disclosure, a plasma printing process to form the surface treatment portion SA may be performed on the first bank region 161. Therefore, in the display apparatus according to another embodiment of the present disclosure, reflection of light used in a process of forming the surface treatment portion SA may be effectively prevented by the second bank region 162. That is, in the display apparatus according to another embodiment of the present disclosure, damage of each emission area R-EA, G-EA and B-EA due to a process of forming the surface treatment portion SA may be effectively prevented.

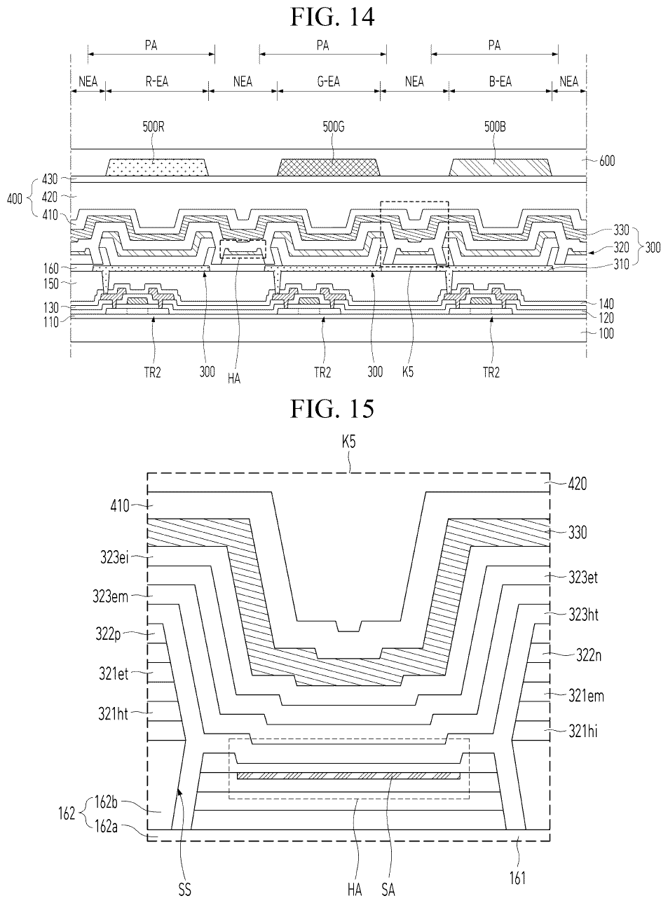

In the display apparatus according to another embodiment of the present disclosure, the bank insulating layer 160 may be formed of various materials. For example, in the display apparatus according to another embodiment of the present disclosure, the second bank region 162 may include a first insulating pattern 162a having a same thickness as the first bank region 161 and a second insulating pattern 162b on the first insulating pattern 162a, the first insulating pattern 162a may include a same material as the first bank region 161, and the second insulating pattern 162b may include a different material from the first insulating pattern 162a, as shown in FIGS. 14 and 15. Thus, in the display apparatus according to another embodiment of the present disclosure, an interface between the first bank region 161 and the first insulating pattern 162a may not be recognized, and an interface between the first insulating pattern 162a and the second insulating pattern 162b may be recognized. For example, the first insulating pattern 162a may be formed simultaneously with the first bank region 161. Therefore, in the display apparatus according to another embodiment of the present disclosure, the degree of freedom in material and forming process of the bank insulating layer 160 may be improved.

As shown in FIG. 15, the second bank region 162 may include a first insulating pattern 162a and a second insulating pattern 162b. The first insulating pattern 162a may have a same thickness as the first bank region 161. The second insulating pattern 162b may be disposed on the first insulating pattern 162a. A side surface SS of the second insulating pattern 162b toward the first bank region 161 may have a reverse taper shape. A portion of the charge generation layer 322 on the first bank region 161 may be separated from a portion of the charge generation layer 322 on the second bank region 162 by the side surface SS of the second insulating pattern 162b.

A thickness of the second insulating pattern 162b may be larger than a thickness of the charge generation layer 322n and 322p. For example, a thickness difference between the first bank region 161 and the second bank region 162 may be larger than the sum of a thickness of the first emission stack 321hi, 321ht, 321em and 321et and a thickness of the charge generation layer 322n and 322p. The high-resistance region HA of the charge generation layer 322n and 322p may be surrounded by the second insulating pattern 162b.

In the display apparatus according to another embodiment of the present disclosure, a side wall of the second insulating pattern 162b toward the first bank region 161 may have a shape of reverse taper. Thus, in the display apparatus according to another embodiment of the present disclosure, a portion of the light-emitting unit 320 overlapping with the first bank region 161 may be separated from a portion of the light-emitting unit 320 on adjacent emission area R-EA, G-EA and B-EA. For example, in the display apparatus according to another embodiment of the present disclosure, a portion of the hole injection layer 321hi, a portion of the first hole transport layer 321ht, a portion of the first emission material layer 321em, a portion of the first electron transport layer 321et, a portion of the n-type charge generating layer 322n, and a portion of the p-type charge generating layer 322p overlapping with the first bank region 161 may be separated from a portion of the hole injection layer 32hi, a portion of the first hole transport layer 321ht, a portion of the first emission material layer 321em, a portion of the first electron transport layer 321et, a portion of the n-type charge generating layer 322n, and a portion of the p-type charge generating layer 322p disposed on the second bank region 162, respectively. Thus, in the display apparatus according to another embodiment of the present disclosure, leakage current may be effectively blocked. Therefore, in the display apparatus according to another embodiment of the present disclosure, light leakage due to leakage current may be significantly reduced. And, in the display apparatus according to another embodiment of the present disclosure, efficiency of each emission area R-EA, G-EA and B-EA may be greatly improved.

In the result, the display apparatus according to the embodiments of the present disclosure may comprise the light-emitting device on the emission area and the bank insulating layer on the non-emission area, wherein the light-emitting device may include the charge generation layer between the first emission stack and the second emission stack, and wherein a portion of the charge generation layer overlapping with the bank insulating layer may have a larger resistance than a portion of the charge generation layer overlapping with the emission area. Thus, in the display apparatus according to the embodiments of the present disclosure, the driving current applied to the light-emitting device may not flow outside the emission area. Thereby, in the display apparatus according to the embodiments of the present disclosure, light leakage due to leakage current may be prevented. And, in the display apparatus according to the embodiments of the present disclosure, efficiency of the light-emitting device may be improved. That is, in the display apparatus according to the embodiments of the present disclosure, power consumption may be reduced by low-power driving.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus comprising:
a first light-emitting device including a first electrode, a first light-emitting unit, and a second electrode, which are sequentially stacked on a first emission area of a device substrate;
a bank insulating layer on a non-emission area of the device substrate, the bank insulating layer defining the first emission area; and
an encapsulation structure on the first light-emitting device and the bank insulation layer,
wherein the first light-emitting unit includes a charge generation layer between a first emission stack and a second emission stack,
wherein the charge generation layer includes a first region between the bank insulating layer and the encapsulation structure, and
wherein the first region of the charge generation layer has a greater resistance than a second region of the charge generation layer overlapping with the first emission area.

2. The display apparatus according to claim 1, wherein the first region of the charge generation layer has a smaller thickness than the second region of the charge generation layer.

3. The display apparatus according to claim 1, wherein the charge generation layer has a stacked structure of a n-type charge generating layer and a p-type charge generating layer, and
wherein at least one of the n-type charge generating layer and the p-type charge generating layer includes a surface treatment portion disposed in the first region.

4. The display apparatus according to claim 3, wherein the surface treatment portion has hydrophobicity.

5. The display apparatus according to claim 3, wherein the p-type charge generating layer is disposed on the n-type charge generating layer,
wherein the surface treatment portion is disposed in an upper portion of the n-type charge generating layer being in contact with the p-type charge generating layer, and
wherein a portion of the p-type charge generating layer being in contact with the surface treatment portion has a smaller thickness than a portion of the p-type charge generating layer disposed outside the surface treatment portion.

6. The display apparatus according to claim 3, wherein the p-type charge generating layer is disposed on the n-type charge generating layer,
wherein the surface treatment portion is disposed in a portion of the p-type charge generating layer overlapping with the bank insulating layer, and
wherein a portion of a functional layer of the second light-emitting stack being in contact with the surface treatment portion has a smaller thickness than a portion of the functional layer disposed outside the surface treatment portion, the functional layer is in contact with the p-type charge generating layer.

7. The display apparatus according to claim 3, wherein a second surface treatment portion is further formed on a functional layer of the first light-emitting stack and the second light-emitting stack, the second surface treatment portion is formed in a portion of the functional layer overlapping the bank insulating layer and overlaps the surface treatment portion.

8. The display apparatus according to claim 1, wherein the bank insulating layer includes a light-absorbing material.

9. The display apparatus according to claim 1, wherein each of the first emission stack and the second emission stack includes at least one emission material layer, and
wherein the emission material layer of each emission stack is disposed outside the first region.

10. The display apparatus according to claim 1, further comprising a second light-emitting device on a second emission area of the device substrate,
wherein the non-emission area is disposed between the first emission area and the second emission area,
wherein the second light-emitting device includes emission stacks and a charge generation layer between the emission stacks, and
wherein the charge generation layer of the second light-emitting device is in contact with the charge generation layer of the first light-emitting device between the bank insulating layer and the encapsulation structure.

11. A display apparatus comprising:
a first electrode on an emission area of a device substrate;
a bank insulating layer on a non-emission area of the device substrate;
a light-emitting unit on the first electrode and the bank insulating layer; and
a second electrode on the light-emitting unit,
wherein the light-emitting unit has a stacked structure of a first emission stack, a charge generation layer, and a second emission stack, and
wherein a resistance between the first emission stack and the second emission stack on the bank insulating layer is larger than a resistance between the first emission stack and the second emission stack on the emission area.

12. The display apparatus according to claim 11, wherein each of the first emission stack and the second emission stack include at least one emission material layer, and
wherein light generated by the second emission stack displays a different color from light generated by the first emission stack.

13. The display apparatus according to claim 11, wherein the bank insulating layer includes a first bank region and a second bank region having a greater thickness than the first bank region,
wherein the second bank region is disposed between the first bank region and the emission area, and
wherein a resistance between the first emission stack and the second electrode on the second bank region is smaller than a resistance between the first emission stack and the second electrode on the first bank region.

14. The display apparatus according to claim 13, wherein the resistance between the first emission stack and the second electrode on the second bank region is a same as a resistance between the first emission stack and the second electrode on the emission area.

15. The display apparatus according to claim 13, wherein a thickness difference between the first bank region and the second bank region is greater than a thickness of the charge generation layer.

16. The display apparatus according to claim 15, wherein the second bank region includes a first insulating pattern having a same thickness as the first bank region and a second insulating pattern disposed on the first insulating pattern,
wherein a side surface of the second insulating pattern toward the first bank region has a reverse taper shape, and
wherein a portion of the charge generation layer on the first bank region is separated from a portion of the charge generation layer on the second bank region by the side surface of the second insulating pattern.

17. The display apparatus according to claim 11, wherein the second emission stack includes a functional layer being in contact with the charge generation layer, and
wherein the functional layer on the bank insulating layer includes a region having a smaller thickness than the functional layer on the emission area.

18. A pixel structure, comprising:
a driving circuit,
a light-emitting device driven by the driving circuit, the light-emitting device including a first electrode, light-emitting unit and a second electrode, which are sequentially stacked on an emission area of a device substrate; and
a bank insulating layer on a non-emission area of the device substrate, the bank insulating layer defining the emission area,
wherein the light-emitting unit includes a plurality of emission stacks and at least one charge generation layer, each of the at least one charge generation layer is disposed between adjacent two emission stacks of the plurality of emission stacks,
wherein each of the at least one charge generation layer includes a first region on the bank insulating layer, and
wherein the first region of each of the at least one charge generation layer has a greater resistance than a second region of corresponding charge generation layer overlapping with the emission area.

19. The display apparatus according to claim 18, wherein the first region of each of the at least one charge generation layer has a smaller thickness than the second region of the corresponding charge generation layer.

20. The display apparatus according to claim 18, wherein each of the at least one charge generation layer has a stacked structure of n-type charge generating layer and a p-type charge generating layer, and
wherein at least one of the n-type charge generating layer and the p-type charge generating layer includes a surface treatment portion disposed in the first region.

21. The display apparatus according to claim 20, wherein the surface treatment portion has hydrophobicity.

22. The display apparatus according to claim 20, wherein the p-type charge generating layer is disposed on the n-type charge generating layer,
wherein the surface treatment portion is disposed in an upper portion of the n-type charge generating layer being in contact with the p-type charge generating layer, and
wherein a portion of the p-type charge generating layer being in contact with the surface treatment portion has a smaller thickness than a portion of the p-type charge generating layer disposed outside the surface treatment portion.

23. The display apparatus according to claim 18, wherein, among the at least one charge generation layer, a horizontal width of the first region of a charge generation layer close to the device substrate is greater than a horizontal width of the first region of a charge generation layer away from the device substrate.
